(19) United States
(12) Patent Application Publication
(10) Pub. No.: US 2026/0049239 A1
(43) Pub. Date: Feb. 19, 2026

(54) POLISHING COMPOSITION FOR SEMICONDUCTOR PROCESS AND METHOD FOR POLISHING SUBSTRATE USING SAME

(71) Applicant: SK ENPULSE CO., LTD., Seongnam-si (KR)

(72) Inventors: Deoksu HAN, Seoul (KR); Seungchul HONG, Seoul (KR)

(73) Assignee: SK ENPULSE CO., LTD., Gyeonggi-do (KR)

(21) Appl. No.: 19/369,789

(22) Filed: Oct. 27, 2025

Related U.S. Application Data
(63) Continuation of application No. PCT/KR2024/005675, filed on Apr. 26, 2024.

(30) Foreign Application Priority Data
Apr. 28, 2023 (KR) 10-2023-0056015

(51) Int. Cl. C09K 3/14; H01L 21/321

(52) U.S. Cl. CPC C09K 3/1463; H01L 21/3212

(57) ABSTRACT

The polishing composition for semiconductor process includes polishing particles, wherein an Rps value calculated by the following Formula 1 is 0.5 to 2:

$$Rps = \frac{Ap}{As} \qquad [ Formula 1 ]$$

in [Formula 1], Ap is a specific surface area of a micropore of the polishing particles, and As is a specific surface area of an external surface of the polishing particles.

### CROSS-REFERENCE TO RELATED APPLICATIONS

Pursuant to 35 USC 120 and 365(c), this application is a continuation of International Application No. PCT/KR2024/005675 filed on Apr. 26, 2024, and claims the benefit under 35 USC 119(a) of Korean Application No. 10-2023-0056015 filed on Apr. 28, 2023, in the Korean Intellectual Property Office, the entire disclosures of which are incorporated herein by reference for all purposes.

### BACKGROUND

### 1. Field

The present disclosure relates to a polishing composition for semiconductor process and a method for polishing a substrate using the same.

### 2. Discussion of Related Art

As semiconductor devices become further miniaturized and highly integrated, finer pattern forming technologies are being used, and accordingly, the surface structure of semiconductor devices becomes more complicated and the step difference between interlayer films becomes larger. As a planarization technique for removing the step difference at a specific film formed on a substrate in manufacturing semiconductor devices, a chemical mechanical polishing (CMP) process is used.

In the CMP process, slurry is supplied to a polishing pad while the substrate is pressed and rotated, and the surface is polished. Depending on the process step, the target to be planarized changes, and the physical properties of the slurry applied also differ.

After metal wiring is formed, it is necessary to maintain sufficient polishing rate and polishing speed while minimizing dishing or erosion.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, the polishing composition for semiconductor process includes polishing particles, wherein an Rps value calculated by the following Formula 1 is 0.5 to 2:

$$Rps = \frac{Ap}{As} \qquad [ Formula 1 ]$$

in [Formula 1], Ap is a specific surface area of a micropore of the polishing particles, and As is a specific surface area of an external surface of the polishing particles.

The Ap may be 25 m²/g to 50 m²/g.

The As may be 10 m²/g to 30 m²/g.

A BET specific surface area of the polishing particles may be 30 m²/g to 80 m²/g.

A specific pore volume of the micropore of the polishing particles may be 0.011 cm³/g to 0.2 cm³/g.

The polishing particles may include primary particles having an average diameter of 15 nm to 40 nm.

The polishing particles may further include secondary particles having an average diameter of 120 nm or more in an amount of 10 wt % or less.

The polishing particles may further include secondary particles having an average diameter of less than 50 nm in an amount of 10 wt % or less.

The polishing composition may include the polishing particles in an amount of 4 wt % to 12 wt %.

A pH of the polishing composition may be 8 to 12.

In another general aspect, the method for manufacturing a substrate includes a process of polishing the substrate using the polishing composition for semiconductor process.

In still another general aspect, the polishing particles are provided, wherein an Rps value calculated by the following Formula 1 is 0.5 to 2:

$$Rps = \frac{Ap}{As} \qquad [ Formula 1 ]$$

in [Formula 1], Ap is a specific surface area of a micropore of the polishing particles, and As is a specific surface area of an external surface of the polishing particles.

The Ap may be 25 m²/g to 50 m²/g.

The As may be 10 m²/g to 30 m²/g.

A BET specific surface area of the polishing particles may be 30 m²/g to 80 m²/g.

A specific pore volume of micropore of the polishing particles may be 0.011 cm³/g to 0.2 cm³/g.

The polishing particles may include primary particles having an average diameter of 15 nm to 40 nm.

The polishing particles may further include secondary particles having an average diameter of 120 nm or more.

The polishing particles may further include secondary particles having an average diameter of less than 50 nm.

Other features and aspects will be apparent from the following detailed description and the claims.

### BRIEF DESCRIPTION OF THE DRAWINGS

FIG. 1 is a graph showing the diameter distribution of secondary particles of polishing particles according to Preparation Examples.

### DETAILED DESCRIPTION

Hereinafter, embodiments will be described in detail with reference to embodiments so that those skilled in the art to which the present disclosure pertains can easily carry out the embodiments. However, the embodiments may be implemented in various different forms, and are not limited to the embodiments described herein.

In this specification, terms such as “about,” “substantially,” and the like, when presented with numerical values, are used in a sense proximate to the numerical values when considering inherent manufacturing and material tolerances, and are used to prevent unscrupulous infringers from unfairly taking advantage of the disclosure containing accurate or absolute values, and to aid in the understanding of the embodiments.

Throughout this specification, the term “a combination thereof” included in a Markush-type expression means a mixture or combination of one or more selected from the group consisting of elements listed in the Markush expression, and means including one or more selected from the group consisting of the elements.

Throughout this specification, the phrase “A and/or B” means “A, B, or A and B.”

Throughout this specification, terms such as “first,” “second,” “A,” “B” and the like are used to distinguish identical terms from each other unless otherwise specifically described.

In this specification, the phrase that B is located on A means that B is located on A, or that B is located on A while another layer is interposed therebetween, and it does not mean that B is necessarily in direct contact with the surface of A.

In this specification, singular expressions, unless otherwise specifically described, are interpreted to include both singular and plural as understood in context.

The object of the present disclosure is to provide a polishing composition for semiconductor process which, when applied to a CMP process, may exhibit excellent polishing rate and may realize a polished surface with reduced defects.

The polishing composition for semiconductor process of the present disclosure, when applied to a CMP process, may exhibit excellent polishing rate and may provide a polished surface with reduced defects.

The inventors of the present disclosure experimentally confirmed that, when a polishing composition for semiconductor process, in which an Rps value (ratio of the specific surface area of the micropore of the polishing particles to the specific surface area of the external surface of the polishing particles) is controlled, is applied to CMP polishing, the polishing composition may exhibit excellent polishing rate with respect to a target substrate to be polished, while effectively reducing the frequency of defect occurrence on the polished surface.

Hereinafter, the embodiments will be specifically described.

### Surface Characteristics of Polishing Particles

The polishing composition for semiconductor process according to the present disclosure includes polishing particles.

An Rps value, which is a ratio of a micropore specific surface area to an external specific surface area of the polishing particles according to the following Formula 1, is 0.5 to 2:

$$Rps = \frac{Ap}{As} \qquad [ Formula 1 ]$$

In Formula 1, Ap is the micropore specific surface area of the polishing particles, and As is the external specific surface area of the polishing particles.

The term “micropore” means a pore having an average diameter of less than 2 nm.

The present disclosure controls the Rps value of polishing particles such as to adjust the degree of irregularity in the shape of the polishing particles and to impart a certain level of roughness to the surface of the polishing particles. Polishing particles having such characteristics may exhibit a wider contact area with the surface to be polished when polishing pressure is applied during a CMP process compared with spherical particles having a smooth surface, thereby providing a superior polishing rate for the surface to be polished. At the same time, since the degree of micropore formation on the surface of the polishing particles is controlled, the durability of the polishing particles may be stably controlled. This in turn makes it possible to effectively reduce the frequency of defect occurrence on the polished surface caused by damaged polishing particles during polishing.

Method for Measuring Rps Value of Polishing Particles is described as follows.

Polishing particles are degassed at 250° C. for 3 hours. The degassed polishing particles are introduced into a specific surface area measuring device, nitrogen adsorption amount onto the polishing particles is measured while relative pressure (p/p°) is increased from 0 to 1.0 at 77.3K, and nitrogen desorption amount from the polishing particles is measured while relative pressure is decreased from 1.0 to 0, thereby obtaining an adsorption/desorption isotherm of nitrogen of the polishing particles. The specific surface area value of the polishing particles is calculated from the adsorption/desorption isotherm of nitrogen by the BET (Brunauer-Emmett-Teller) method, and the value is defined as a BET specific surface area of the polishing particles.

Here, p is the equilibrium pressure of nitrogen gas, and p° is the saturated vapor pressure of nitrogen gas.

A t-plot is generated from the adsorption/desorption isotherm of nitrogen according to the Harkins-Jura equation, and an external specific surface area value (As) of the polishing particles is calculated. Thereafter, a value obtained by subtracting the As value from the BET specific surface area value of the polishing particles is defined as the Ap value.

The Rps value is calculated by dividing the Ap value by the As value.

As an example, a TriStar II 3020 model manufactured by Micromeritics may be used as the specific surface area measuring instrument.

The Rps value of the polishing particles may be 0.5 to 2. The Rps value may be 0.7 or more. The Rps value may be 0.9 or more. The Rps value may be 1.8 or less. The Rps value may be 1.5 or less. In this case, while enhancing the polishing rate of the polishing composition for a target substrate, the defect occurrence caused by the polishing particles may be effectively suppressed.

The Ap value may be 25 m²/g to 50 m²/g. The Ap value may be 26 m²/g or more.

The Ap value may be 27 m²/g or more. The Ap value may be 40 m²/g or less. The Ap value may be 35 m²/g or less. The Ap value may be 32 m²/g or less. In this case, appropriate roughness may be imparted to the surface of the polishing particles to improve the polishing efficiency of the polishing composition.

The As value may be 10 m²/g to 30 m²/g. The As value may be 15 m²/g or more. The As value may be 20 m²/g or more. The As value may be 22 m²/g or more. The As value may be 28 m²/g or less. The As value may be 26 m²/g or less. In this case, the polishing composition may exhibit improved polishing rate and stable durability at the same time.

The specific surface area of the polishing particles may be influenced not only by the shape of the polishing particles but also by the size of the polishing particles. Specifically, the specific surface area of the polishing particles tends to increase as the size of the polishing particles decreases. The present disclosure may control parameter values related to the specific surface area of the polishing particles such that both of particle size distribution and shape of the polishing particles may be appropriately controlled within a proper range.

The BET specific surface area of the polishing particles may be 30 m²/g to 80 m²/g. The BET specific surface area may be 40 m²/g or more. The BET specific surface area may be 45 m²/g or more. The BET specific surface area may be 48 m²/g or more. The BET specific surface area may be 70 m²/g or less. The BET specific surface area may be 65 m²/g or less. The BET specific surface area may be 60 m²/g or less. In this case, while reducing the frequency of occurrence of defects formed by small-sized polishing particles being adsorbed on the polished surface, polishing characteristics of the polishing composition may be effectively improved.

The present disclosure may control structural characteristics of micropores inside the polishing particles. Polishing particles having such characteristics may have irregular shapes while maintaining stable durability.

The specific pore volume of micropores of the polishing particles may be 0.011 cm³/g to 0.2 cm³/g. The specific pore volume may be 0.012 cm³/g or more. The specific pore volume may be 0.15 cm³/g or less. The specific pore volume may be 0.1 cm³/g or less. The specific pore volume may be 0.05 cm³/g or less. The specific pore volume may be 0.03 cm³/g or less. The specific pore volume may be 0.02 cm³/g or less. In this case, damage to the polishing particles by polishing pressure may be suppressed, and defects occurring due to particles derived from the polishing particles being adsorbed onto the polished surface may be suppressed.

The average diameter of micropores of the polishing particles may be 15 nm to 40 nm. The average diameter may be 18 nm or more. The average diameter may be 20 nm or more. The average diameter may be 35 nm or less. The average diameter may be 30 nm or less. The average diameter may be 28 nm or less. In this case, the polishing particles may not easily break by external force and may have a more stable structure.

The specific pore volume and the average diameter of micropores are measured through a specific surface area measuring instrument. The specific measuring conditions adopted for measuring the specific pore volume and the average diameter of micropores are the same as those adopted in measuring the BET specific surface area.

### Diameter Distribution of the Polishing Particles

The polishing particles may include secondary particles having a diameter of 120 nm or more in an amount of 10 wt % or less. The polishing particles may include secondary particles having a diameter of 120 nm or more in an amount of 8 wt % or less. The polishing particles may include secondary particles having a diameter of 120 nm or more in an amount of 0.1 wt % or more. In this case, scratches formed on the polished surface due to large-diameter secondary particles during polishing may be effectively suppressed.

The polishing particles may include secondary particles having a diameter of less than 50 nm in an amount of 10 wt % or less. The polishing particles may include secondary particles having a diameter of less than 50 nm in an amount of 8 wt % or less. The polishing particles may include secondary particles having a diameter of less than 50 nm in an amount of 0.1 wt % or more. In this case, the frequency of relatively small-sized particles among the polishing particles being adsorbed onto the polished surface due to interaction with the polished surface may be reduced.

The D50 of the secondary particles of the polishing particles may be 40 nm or more. The D50 may be 45 nm or more. The D50 may be 50 nm or more. The D50 may be 55 nm or more. The D50 may be 100 nm or less. The D50 may be 95 nm or less. The D50 may be 90 nm or less. The D50 may be 85 nm or less. The D50 may be 80 nm or less. In this case, while stably controlling the occurrence of defects on the polished surface, excellent polishing characteristics may be imparted to the polishing composition.

The diameter of secondary particles of the polishing particles is measured through DLS (Dynamic Light Scattering). As an example, the diameter of the secondary particles of the polishing particles is measured using a particle size analyzer, Zetasizer nano-ZS model, manufactured by Malvern Panalytical.

The D50 of the primary particles of the polishing particles may be 15 nm or more. The D50 may be 20 nm or more. The D50 may be 25 nm or more. The D50 may be 55 nm or less. The D50 may be 50 nm or less. The D50 may be 45 nm or less. In this case, while stably reducing the frequency of defects occurring by polishing particles being adsorbed on the polished surface, the polishing composition may exhibit excellent polishing characteristics.

The diameter of the primary particles of the polishing particles is measured through TEM (Transmission Electron Microscope).

The degree of aggregation of the polishing particles may be 3 or less. The degree of aggregation may be 2.8 or less. The degree of aggregation may be 2.5 or less. The degree of aggregation may be 2.3 or less. The degree of aggregation may be 1.1 or more. The degree of aggregation may be 1.5 or more. In this case, the polishing composition may exhibit stable reproducibility of polishing characteristics and polishing rate.

The degree of aggregation of the polishing particles is measured by a method generally adopted in the CMP slurry field.

### Composition of Polishing Particles

The polishing particles may include metal oxide particles. The polishing particles may include silica. The polishing particles may include colloidal silica.

The polishing particles may include colloidal silica in an amount of 70 wt % or more. The polishing particles may include colloidal silica in an amount of 80 wt % or more. The polishing particles may include colloidal silica in an amount of 90 wt % or more. The polishing particles may be colloidal silica.

The polishing particles may include alkali metals in an amount of 1000 ppb (based on weight) or less. The polishing particles may include alkali metals in an amount of 800 ppb (based on weight) or less. The polishing particles may include alkali metals in an amount of 600 ppb (based on weight) or less. The polishing particles may include alkali metals in an amount of 400 ppb (based on weight) or less. The polishing particles may include alkali metals in an amount of 50 ppb (based on weight) or more.

The polishing particles may include heavy metals in an amount of 500 ppb (based on weight) or less. The polishing particles may include heavy metals in an amount of 400 ppb (based on weight) or less. The polishing particles may include heavy metals in an amount of 300 ppb (based on weight) or less. The polishing particles may include heavy metals in an amount of 200 ppb (based on weight) or less. The polishing particles may include heavy metals in an amount of 10 ppb (based on weight) or more.

In such a case, when polishing a target substrate, in which wiring is exposed, it may effectively prevent metallic impurities from being adsorbed or remaining on the polished surface, thereby preventing electrical defects such as insulation failure of circuits or short-circuiting of wiring.

### Composition and Physical Properties of Polishing Composition for Semiconductor Process

The polishing composition for semiconductor process may include the polishing particles in an amount of 4 wt % to 12 wt %. The polishing composition for semiconductor process may include the polishing particles in an amount of 6 wt % or more. The polishing composition for semiconductor process may include the polishing particles in an amount of 10 wt % or less. In such a polishing composition, the polishing particles may be stably dispersed in the composition, and may help reduce the frequency of defect occurrence during the polishing process.

The polishing composition for semiconductor process may further include an additive. The additive is not limited as long as it is conventionally applied in the CMP field. For example, the additive may be at least one selected from the group consisting of a nonionic polymer, a chelating agent, an oxidizing agent, an acid component, a pH adjuster, a dispersant, a polishing rate enhancer, a polishing controller, a polishing pad protector, and a preservative.

The polishing composition for semiconductor process may further include a nonionic polymer to further improve the dispersibility of the polishing particles in the polishing composition. Specifically, the nonionic polymer included in the polishing composition may be adsorbed onto the surface of the polishing particles to increase the dispersibility of the polishing particles. In addition, the nonionic polymer not adsorbed onto the surface of the polishing particles may have steric hindrance effects and the like, thereby further enhancing the dispersion stability of the polishing particles. In particular, the nonionic polymer may allow the polishing composition for semiconductor process to have more stable dispersion stability even in an acidic environment. Such a nonionic polymer may reduce the occurrence of defects caused by polishing on the substrate during the polishing process.

The nonionic polymer may be at least one selected from the group consisting of polyethylene glycol, polypropylene glycol, polyvinylpyrrolidone, polyethylene oxide, polypropylene oxide, polyalkylene oxide, polyoxyethylene oxide, polyethylene oxide-propylene oxide copolymer, cellulose, methylcellulose, methylhydroxyethylcellulose, methylhydroxypropylcellulose, hydroxyethylcellulose, carboxymethylcellulose, carboxymethylhydroxyethylcellulose, sulfoethylcellulose, and carboxymethylsulfoethylcellulose.

The nonionic polymer may have a weight average molecular weight of less than 25,000 g/mol. The weight average molecular weight may be 1,000 g/mol or more and less than 25,000 g/mol. In such a case, the nonionic polymer may exhibit excellent solubility and further improve the dispersion stability of the polishing particles.

The polishing composition for semiconductor process may include the nonionic polymer in an amount of 0.01 wt % to 5 wt %. The polishing composition for semiconductor process may include the nonionic polymer in an amount of 0.1 wt % or more. The polishing composition for semiconductor process may include the nonionic polymer in an amount of 2 wt % or less. In such a case, the polishing composition may help reduce the frequency of defect occurrence on the surface of the polished substrate, and may suppress contamination such as reattachment of particles on the surface.

The polishing composition for semiconductor process may further include a chelating agent. Through the polishing process, metals or metal ions removed from the surface of the substrate may be reattached or remain on the substrate surface to form defects. In particular, metals such as tungsten may be easily dissolved in the polishing composition under specific conditions, but may have characteristics that are easily attached to the polished surface. The chelating agent may be adsorbed to such metals or metal ions, thereby easily removing the metals and the like. Through this, the polishing composition may further increase the polishing rate and may effectively suppress defect formation on the substrate surface due to particle reattachment.

For example, the chelating agent may be at least one selected from the group consisting of butyric acid, citric acid, tartaric acid, succinic acid, oxalic acid, acetic acid, adipic acid, capric acid, caproic acid, caprylic acid, carboxylic acid, glutaric acid, glutamic acid, glycolic acid, thioglycolic acid, formic acid, mandelic acid, fumaric acid, lactic acid, lauric acid, malic acid, maleic acid, malonic acid, myristic acid, palmitic acid, phthalic acid, isophthalic acid, terephthalic acid, citraconic acid, propionic acid, pyruvic acid, stearic acid, valeric acid, benzoic acid, phenylacetic acid, naphthoic acid, aspartic acid, amino acid, and ethylenediaminetetraacetic acid.

As the amino acid, glycine, α-alanine, β-alanine, L-aspartic acid, N-methylglycine (methylglycine), and combinations thereof may be used.

The chelating agent may include 2 or more carboxyl groups or alcohol groups in the molecule. Two or more kinds of chelating agents including 2 or more carboxyl groups or alcohol groups in the molecule may be applied. Specifically, the chelating agent may include at least one selected from the group consisting of EDTA (ethylenediaminetetraacetic acid), glycine, carboxylic acids, and combinations thereof. The carboxylic acids mean compounds including at least one or two or more carboxyl groups in each molecule.

The polishing composition for semiconductor process may include the chelating agent in an amount of 0.003 wt % to 0.5 wt %. The polishing composition for semiconductor process may include the chelating agent in an amount of 0.005 wt % or more. The polishing composition for semiconductor process may include the chelating agent in an amount of 0.3 wt % or less. In such a case, the polishing rate of the polishing composition may be controlled to an appropriate level, and the frequency of defect occurrence on the surface of the substrate may be reduced.

The polishing composition for semiconductor process may further include an oxidizing agent. The oxidizing agent may oxidize metals such as tungsten to create an environment, which allows the substrate surface to be more easily planarized, and may play a role in improving the polishing rate and the etching rate.

The oxidizing agent may be at least one selected from the group consisting of hydrogen peroxide, urea hydrogen peroxide, urea, percarbonate, periodic acid, periodate, perchloric acid, perchlorate, perbromic acid, perbromate, perboric acid, perborate, permanganic acid, permanganate, persulfate, bromate, chlorate, chlorite, chromate, iodate, iodine acid, ammonium persulfate, benzoyl peroxide, calcium peroxide, barium peroxide, sodium peroxide, and percarbamide.

The polishing composition for semiconductor process may include the oxidizing agent in an amount of 0.01 wt % to 5 wt %. In such a case, the composition may exhibit excellent polishing properties for metals, and may suppress the formation of an oxide film on the metals to be polished during the polishing process.

The polishing composition for semiconductor process may further include a copper corrosion inhibitor. The copper corrosion inhibitor may include an azole-based compound.

The azole-based compound may include one selected from the group consisting of benzotriazole (BTA), 5-methyl-1H-benzotriazole (5-MBTA), 3-amino-1,2,4-triazole, 5-phenyl-1H-tetrazole, 3-amino-5-methyl-4H-1,2,4-triazole, 5-aminotetrazole (ATZ), 1,2,4-triazole, tolyltriazole, and combinations thereof.

The azole-based compound may include one selected from the group consisting of 5-aminotetrazole (ATZ), 5-methyl-1H-benzotriazole (5-MBTA), and combinations thereof.

The azole-based compound may act on the copper surface during the polishing process to play a role in preventing copper corrosion.

The azole-based compound may be included in an amount of 0.02 to 2.00 parts by weight, 0.03 to 1.5 parts by weight, or 0.5 to 1.5 parts by weight, based on 100 parts by weight of the polishing particles.

In such a range, when including the azole-based compound, the polishing composition for semiconductor process may obtain the effect of preventing corrosion of the copper surface, and in particular, may provide a strong corrosion prevention effect on relatively large surfaces such as via hole surfaces.

The polishing composition for semiconductor process may further include an acid component. The acid component may be at least one selected from the group consisting of hydrochloric acid, phosphoric acid, sulfuric acid, hydrofluoric acid, bromic acid, iodic acid, formic acid, malonic acid, maleic acid, oxalic acid, acetic acid, adipic acid, citric acid, adipic acid, acetic acid, propionic acid, fumaric acid, lactic acid, salicylic acid, pimelic acid, benzoic acid, succinic acid, phthalic acid, butyric acid, glutaric acid, glutamic acid, glycolic acid, lactic acid, aspartic acid, tartaric acid, and salts thereof.

The polishing composition for semiconductor process may further include a pH adjuster together with the acid component. The pH adjuster may be selected from the group consisting of ammonia, aminomethylpropanol, tetramethylammonium hydroxide, potassium hydroxide, sodium hydroxide, magnesium hydroxide, rubidium hydroxide, cesium hydroxide, sodium bicarbonate, sodium carbonate, imidazole, and combinations thereof.

The polishing composition for semiconductor process may further include a dispersant.

The dispersant may prevent aggregation between polishing particles in the polishing composition and may uniformly disperse the particles. The cationic dispersant may increase the zeta potential of the polishing composition to a positive value, and the anionic dispersant may decrease the zeta potential of the polishing composition to a negative value.

The dispersant may include an anionic low-molecular compound, a cationic polymer, and an organic acid.

The anionic low-molecular compound of the dispersant may be selected from the group consisting of oxalic acid, citric acid, polysulfonic acid, polyacrylic acid, polymethacrylic acid, and combinations thereof.

The cationic polymer of the dispersant may be selected from the group consisting of polylysine, polyethyleneimine, benzethonium chloride, bronidox, cetrimonium bromide, cetrimonium chloride, dimethyldioctadecyl ammonium chloride, tetramethylammonium hydroxide, distearyldimethyl ammonium chloride, polyaryl amine, and combinations thereof.

The organic acid of the dispersant may be selected from the group consisting of hydroxybenzoic acid, ascorbic acid, picolinic acid, glutamic acid, tryptophan, aminobutyric acid, and combinations thereof.

The polishing rate enhancer may be an additive for increasing the polishing rate of the target substrate or wiring, and may be selected from the group consisting of potassium nitrate, ferric nitrate, ammonium hydroxide, citric acid, acetic acid, and combinations thereof.

The polishing controller may be for minimizing adsorption of the polishing composition on the metal surface, and may include ammonium compounds, potassium nitrate, amino acids, salts thereof, or the like.

The polishing composition for semiconductor process may include a solvent. The solvent may be water, and specifically, may be ultrapure water.

The polishing composition for semiconductor process may have a pH of 8 to 12. The pH may be 9 or more. The pH may be 11 or less. In such a case, the dispersibility of the polishing particles and the polymer included in the polishing composition may be stably controlled. In addition, it may contribute to effectively suppressing defect occurrence on the polished surface caused by adsorption of polishing particles.

The polishing composition for semiconductor process may have a zeta potential of −80 mV to −20 mV. The zeta potential value may be −75 mV or more. The zeta potential value may be −70 mV or more. The zeta potential value may be −65 mV or more. The zeta potential value may be −60 mV or more. The zeta potential value may be −25 mV or less. The zeta potential value may be −30 mV or less. The zeta potential value may be −35 mV or less. The zeta potential value may be −40 mV or less. In such a case, the polishing particles may be stably dispersed in the polishing composition. In addition, the frequency of defect occurrence such as scratches on the polished surface caused by the polishing particles may be effectively reduced.

The zeta potential value of the polishing composition may be measured using a zeta potential measuring instrument.

### Polishing Characteristics of the Polishing Composition for Semiconductor Process

The polishing rate of the polishing composition for semiconductor process for the silicon oxide film may be 1350 Å/min or more. The polishing rate may be 1450 Å/min or more. The polishing rate may be 1550 Å/min or more. The polishing rate may be 1650 Å/min or more. The polishing rate may be 3500 Å/min or less. The polishing rate may be 3000 Å/min or less. The polishing rate may be 2500 Å/min or less.

The PI_{S} value of the polishing composition for semiconductor process according to the following Formula 2-1 may be 200 Å/(min-wt %) or more:

$${PI}_{S} = \frac{{P}_{S}}{C} \qquad [ Formula 2 - 1 ]$$

In Formula 2-1, PS is the polishing rate of the polishing composition for semiconductor process for the silicon oxide film [unit: Å/min].

In Formula 2-1, C is the content of the polishing particles in the polishing composition for semiconductor process [unit: wt %].

The PI_{S} value may be 200 Å/(min-wt %) or more. The PI_{S} value may be 210 Å/(min-wt %) or more. The PI_{S} value may be 220 Å/(min-wt %) or more. The PI_{S} value may be 300 Å/(min-wt %) or less.

The polishing rate of the polishing composition for semiconductor process for the barrier film including tantalum and tantalum nitride may be 780 Å/min or more. The polishing rate may be 800 Å/min or more. The polishing rate may be 830 Å/min or more. The polishing rate may be 1200 Å/min or less.

The PI_{T} value of the polishing composition for semiconductor process according to the following Formula 2-2 may be 200 Å/(min-wt %) or more:

$${PI}_{T} = \frac{{P}_{T}}{C} \qquad [ Formula 2 - 2 ]$$

In Formula 2-2, P_{T} is the polishing rate of the polishing composition for semiconductor process for the barrier film including tantalum and tantalum nitride [unit: Å/min].

In Formula 2-2, C is the content of the polishing particles in the polishing composition for semiconductor process [unit: wt %].

The PI_{T} value may be 80 Å/(min-wt %) or more. The PI_{T} value may be 85 Å/(min-wt %) or more. The PI_{T} value may be 90 Å/(min-wt %) or more. The PI_{T} value may be 95 Å/(min-wt %) or more. The PI_{T} value may be 100 Å/(min-wt %) or more. The PI_{T} value may be 200 Å/(min-wt %) or less.

The polishing rate of the polishing composition for semiconductor process for the copper film may be 850 Å/min or more. The polishing rate may be 900 Å/min or more. The polishing rate may be 950 Å/min or more. The polishing rate may be 1000 Å/min or more. The polishing rate may be 1050 Å/min or more. The polishing rate may be 1100 Å/min or more. The polishing rate may be 2500 Å/min or less.

The PI_{C} value of the polishing composition for semiconductor process according to the following Formula 2-3 may be 100 Å/(min-wt %) or more:

$${PI}_{C} = \frac{{P}_{C}}{C} \qquad [ Formula 2 - 3 ]$$

In Formula 2-3, Pc is the polishing rate of the polishing composition for semiconductor process for the copper film [unit: Å/min].

In Formula 2-3, C is the content of the polishing particles in the polishing composition for semiconductor process [unit: wt %].

The PI_{C} value may be 110 Å/(min-wt %). The PI_{C} value may be 120 Å/(min-wt %) or more. The PI_{C} value may be 130 Å/(min-wt %) or more. The PI_{C} value may be 140 Å/(min-wt %) or more. The PI_{C} value may be 250 Å/(min-wt %) or less. The PI_{C} value may be 200 Å/(min-wt %) or less.

In such a case, the polishing composition may exhibit excellent polishing rate for the target substrate, in which the wiring, oxide film, and barrier film are simultaneously exposed.

The polishing rate for each thin film may be measured under the conditions of a pressure of 2.2 psi, a carrier speed of 87 rpm, a platen speed of 93 rpm, and a slurry flow rate of 250 ml/min.

When measuring the polishing rate for each thin film, the polishing equipment may be, for example, the AP-300 model of CTS Co.

### Manufacturing Method of the Polishing Composition for Semiconductor Process

The manufacturing method of the polishing composition for semiconductor process according to the present disclosure may include preparing polishing particles and preparing the polishing composition for semiconductor process including the polishing particles.

The preparing polishing particles may include preparing a first polishing particle composition and a second polishing particle composition, and a reaction process of obtaining the polishing particles from a reaction solution obtained by mixing the first polishing particle composition and the second polishing particle composition.

The first polishing particle composition may include an organic silicon compound and a first organic solvent.

The organic silicon compound may be an alkoxy silane-based compound. The organic silicon compound may be, for example, TEOS (tetraethoxysilane) or TMOS (tetramethoxysilane).

The first organic solvent may be, for example, ethanol, methanol, or isopropyl alcohol.

The first polishing particle composition may include 20 parts by weight to 50 parts by weight of the organic silicon compound based on 100 parts by weight of the first organic solvent. The first polishing particle composition may include 25 parts by weight or more of the organic silicon compound based on 100 parts by weight of the first organic solvent. The first polishing particle composition may include 45 parts by weight or less of the organic silicon compound based on 100 parts by weight of the first organic solvent.

The first polishing particle composition may be prepared by mixing the organic silicon compound in the first organic solvent in a double-jacket reactor. However, the method of preparing the first polishing particle composition is not limited thereto.

The second polishing particle composition may include water, a catalyst, and a second organic solvent.

The second polishing particle composition may include 1 part by weight to 15 parts by weight of water based on 100 parts by weight of the second organic solvent. The second polishing particle composition may include 3 parts by weight or more of water based on 100 parts by weight of the second organic solvent. The second polishing particle composition may include 10 parts by weight or less of water based on 100 parts by weight of the second organic solvent.

The catalyst may participate in hydrolysis and polymerization reactions of the organic silicon compound during the reaction process, thereby contributing to controlling the shape and particle size distribution of the polishing particles.

The catalyst may be selected from the group consisting of potassium hydroxide, sodium hydroxide, ammonia, TMAH (tetramethylammonium hydroxide), and TEA (triethanolamine).

The second polishing particle composition may include 0.5 parts by weight or more of the catalyst based on 100 parts by weight of the second organic solvent. The second polishing particle composition may include 1 part by weight or more of the catalyst based on 100 parts by weight of the second organic solvent. The second polishing particle composition may include 10 parts by weight or less of the catalyst based on 100 parts by weight of the second organic solvent. The second polishing particle composition may include 7 parts by weight or less of the catalyst based on 100 parts by weight of the second organic solvent.

The second organic solvent may be, for example, ethanol, methanol, or isopropyl alcohol. The second organic solvent may be the same compound as the first organic solvent.

In the reaction process, the first polishing particle composition and the second polishing particle composition may be mixed to prepare a reaction solution. To prepare the reaction solution, the second polishing particle composition may be added to the first polishing particle composition, or the first polishing particle composition may be added to the second polishing particle composition. Specifically, the first polishing particle composition may be added to the second polishing particle composition.

In the reaction process, the polishing particles may be obtained through hydrolysis and polymerization reactions of the organic silicon compound. The present disclosure may control the contents of each component in the reaction solution and the reaction temperature and the like, to adjust the shape characteristics and particle size distribution of the polishing particles obtained within a predetermined range set in the present disclosure.

In the reaction process, the reaction solution may include 60 parts by weight to 120 parts by weight of the second polishing particle composition based on 100 parts by weight of the first polishing particle composition. The reaction solution may include 65 parts by weight or more of the second polishing particle composition based on 100 parts by weight of the first polishing particle composition. The reaction solution may include 70 parts by weight or more of the second polishing particle composition based on 100 parts by weight of the first polishing particle composition. The reaction solution may include 100 parts by weight or less of the second polishing particle composition based on 100 parts by weight of the first polishing particle composition.

The reaction solution may include 3 parts by weight or more of water based on 100 parts by weight of the organic silicon compound. The reaction solution may include 5 parts by weight or more of water based on 100 parts by weight of the organic silicon compound.

The reaction solution may include 10 parts by weight or more of water based on 100 parts by weight of the organic silicon compound. The reaction solution may include 50 parts by weight or less of water based on 100 parts by weight of the organic silicon compound. The reaction solution may include 30 parts by weight or less of water based on 100 parts by weight of the organic silicon compound. The reaction solution may include 20 parts by weight or less of water based on 100 parts by weight of the organic silicon compound.

The reaction solution may include 1 part by weight or more of the catalyst based on 100 parts by weight of the organic silicon compound. The reaction solution may include 3 parts by weight or more of the catalyst based on 100 parts by weight of the organic silicon compound. The reaction solution may include 4 parts by weight or more of the catalyst based on 100 parts by weight of the organic silicon compound. The reaction solution may include 20 parts by weight or less of the catalyst based on 100 parts by weight of the organic silicon compound. The reaction solution may include 15 parts by weight or less of the catalyst based on 100 parts by weight of the organic silicon compound. The reaction solution may include 13 parts by weight or less of the catalyst based on 100 parts by weight of the organic silicon compound.

In such a case, the polishing particles having the shape characteristics and particle size distribution intended by the present disclosure may be obtained.

In the reaction process, the reaction temperature may be set to 20° C. to 60° C. The reaction temperature may be 30° C. or more. The reaction temperature may be 40° C. or more. The reaction temperature may be 55° C. or less. In such a case, the synthesis of the polishing particles may be smoothly carried out.

In the reaction process, the reaction time may be 2 hours to 10 hours. The reaction time may be 3 hours or more. The reaction time may be 4 hours or more. The reaction time may be 8 hours or less. The reaction time may be 7 hours or less. In such a case, the polishing particles may contribute to having the size and shape intended by the present disclosure.

The polishing particles may be prepared by reacting a silicate-based precursor and an alkoxy silane-based precursor.

The descriptions of the surface characteristics, diameter distribution, and composition of the polishing particles are omitted, since they overlap with the previous descriptions.

In the manufacturing step, the polishing particles and a solvent may be mixed to prepare the polishing composition for semiconductor process. The polishing composition for semiconductor process may further include an additive together with the polishing particles and the solvent after purification.

The descriptions of the composition and physical properties of the polishing composition for semiconductor process are omitted, since they overlap with the previous descriptions.

### Method for Manufacturing a Substrate

The method for manufacturing a substrate of the present disclosure may include polishing the substrate by applying the polishing composition for semiconductor process as a slurry.

The substrate may include at least one of an insulating film, a metal wiring, or a barrier layer on an upper surface. The metal wiring may include copper or tungsten. When the metal wiring includes copper, the barrier layer may include tantalum and nitrides thereof. When the metal wiring includes tungsten, the barrier layer may include titanium and nitrides thereof.

Specifically, the polishing the substrate may be carried out such that the substrate to be polished is brought into contact with a polishing pad together with the polishing composition for semiconductor process supplied from a spray nozzle, while a polishing head fixing the substrate rotates and a platen with the polishing pad attached also rotates.

The polishing the substrate may further include, as necessary, conditioning the surface of the polishing pad before polishing.

The polishing composition for semiconductor process may penetrate toward the substrate and polish the wafer being in contact with the polishing pad.

In polishing the substrate, a pressure of 6.89 kPa to 48.26 kPa may be applied. The pressure may be 13.79 kPa to 34.47 kPa.

The polishing the substrate may be carried out for 50 seconds to 10 minutes. However, it may be changed depending on the intended degree of polishing.

The descriptions of the polishing composition for semiconductor process are omitted, since they overlap with the previous descriptions.

The method for manufacturing a substrate may further include a cleaning process of cleaning the substrate after polishing.

The cleaning process may be carried out by cleaning the polished substrate with purified water and inert gas.

### Polishing Particles

The polishing particles according to the present disclosure have an Rps value, which is a ratio of a specific surface area of a micropore of the polishing particles to a specific surface area of an external surface of the polishing particles according to the following Formula 1, of 0.5 to 2:

$$Rps = \frac{Ap}{As} \qquad [ Formula 1 ]$$

In Formula 1, Ap is a specific surface area of a micropore of the polishing particles, and As is a specific surface area of an external surface of the polishing particles.

The Ap value may be 25 m²/g to 50 m²/g.

The As value may be 10 m²/g to 30 m²/g.

The BET specific surface area of the polishing particles may be 30 m²/g to 80 m²/g.

The specific pore volume of the micropores of the polishing particles may be 0.011 cm³/g to 0.2 cm³/g or less.

The average diameter of the micropores of the polishing particles may be 15 nm to 40 nm.

When the polishing particles are introduced into ultrapure water, the polishing particles may include secondary particles having a diameter of 120 nm or more in an amount of 10 wt % or less.

When the polishing particles are introduced into ultrapure water, the polishing particles may include secondary particles having a diameter of less than 50 nm in an amount of 10 wt % or less.

The polishing particles are the same particles as the polishing particles of the polishing composition described above. The descriptions of the surface characteristics, particle size distribution, composition, and manufacturing method of the polishing particles are omitted, since they overlap with the previous descriptions.

Hereinafter, specific embodiments will be described in more detail. The following embodiments are merely examples provided to aid in understanding the present invention, and the scope of the present invention is not limited thereto.

### Preparation Example: Manufacture of Polishing Particles

Preparation Example 1: In a first double-jacket reactor, 15 parts by weight of an organic silicon compound were mixed with 41 parts by weight of a first organic solvent to prepare a total of 56 parts by weight of a first polishing particle preparation composition. In a second double-jacket reactor, 1 part by weight of a catalyst and 2 parts by weight of water were introduced into 41 parts by weight of a second organic solvent to prepare a total of 44 parts by weight of a second polishing particle preparation composition. The temperature of the second double-jacket reactor was set to 45° C., and the first polishing particle preparation composition was introduced into the second polishing particle preparation composition, and a hydrolysis and polymerization reaction was carried out for 5 hours to obtain polishing particles.

As the organic silicon compound, TEOS (tetraethoxysilane) was applied, the first organic solvent and the second organic solvent were ethanol and isopropyl alcohol, respectively, and ammonia was the catalyst.

Preparation Example 2: Polishing particles were manufactured under the same conditions as in Preparation Example 1, except that in the first polishing particle preparation composition, 4.5 parts by weight of the organic silicon compound and 45.75 parts by weight of the first organic solvent were included, and in the second polishing particle preparation composition, 3 parts by weight of water and 45.75 parts by weight of the second organic solvent were included.

Preparation Example 3: Polishing particles were manufactured under the same conditions as in Preparation Example 1, except that in the first polishing particle preparation composition, 4.5 parts by weight of the organic silicon compound and 43.25 parts by weight of the first organic solvent were included, and in the second polishing particle preparation composition, 8 parts by weight of water and 43.25 parts by weight of the second organic solvent were included.

The process conditions for each preparation example are described in Table 1 below.

### Preparation Example: Manufacture of Polishing Composition

Example 1: Into ultrapure water serving as a solvent, 8 wt % of the polishing particles according to Preparation Example 1, 0.4 wt % of citric acid, 0.2 wt % of benzotriazole, 0.2 wt % of polyethylene glycol, and 0.2 wt % of hydrogen peroxide were introduced and mixed to prepare a polishing composition of a total of 100 wt %.

Comparative Example 1: A polishing composition of a total of 100 wt % was prepared under the same conditions as in Example 1, except that 16 wt % of the polishing particles according to Preparation Example 2 were included as the polishing particles.

Comparative Example 2: A polishing composition of a total of 100 wt % was prepared under the same conditions as in Example 1, except that 8 wt % of the polishing particles according to Preparation Example 2 were included as the polishing particles.

Comparative Example 3: A polishing composition of a total of 100 wt % was prepared under the same conditions as in Example 1, except that 8 wt % of the polishing particles according to Preparation Example 3 were included as the polishing particles.

For each of the examples and comparative examples, the polishing particle content in the polishing composition, the D50 of the secondary particles of the polishing particles, the zeta potential, and the pH were applied as described in Table 1 below.

### Evaluation Example: Measurement of Surface Characteristics of Polishing Particles

The Ap value, As value, BET specific surface area value, micropore specific volume, and average diameter of micropores of the polishing particles in each preparation example were measured using the surface area measurement equipment “TriStar II 3020” manufactured by Micromeritics.

For the measurement, after degassing the polishing particles at 250° C. for 3 hours, the degassed polishing particles were introduced into the surface area measurement equipment, and the amount of nitrogen adsorbed into the polishing particles was measured while increasing the relative pressure (p/p°) from 0 to 1.0 at 77.3K, and the amount of nitrogen desorbed from the polishing particles was measured, while decreasing the relative pressure from 1.0 to 0, thereby obtaining the nitrogen adsorption isotherm and nitrogen desorption isotherm of the polishing particles. From the nitrogen adsorption/desorption isotherms, the Ap value, As value, BET specific surface area value, micropore specific volume, and average diameter of micropores were calculated, and from the Ap value and As value, the Rps value was calculated.

The measurement and calculation results for each preparation example are described in Table 2 below.

### Evaluation Example: Measurement of Secondary Particle Size Distribution of Polishing Particles

The secondary particle size distribution of the polishing particles in each preparation example was measured using the particle size analyzer “Zetasizer nano-ZS” manufactured by Malvern Panalytical.

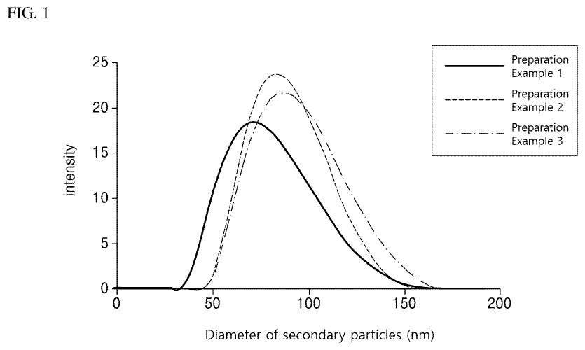

The measurement results for each preparation example are described in Table 3 and FIG. 1 below.

### Evaluation Example: Measurement of Polishing Rate

The polishing compositions of the respective examples and comparative examples were applied as slurry to measure the polishing rates with respect to a silicon oxide film, a barrier film including tantalum and tantalum nitride, and a copper film, each formed on a wafer having a diameter of 300 mm. For each thin film, the polishing rate was measured under the conditions of a polishing time of 60 seconds, a pressure of 2.2 psi, a carrier speed of 93 rpm, a platen speed of 87 rpm, and a slurry flow rate of 300 ml/min, and the polisher used was the AP-300 model manufactured by CTS.

Subsequently, based on the measured polishing rate values, the PI_{S} value according to the above Formula 2-1, the PI_{T} value according to the above Formula 2-2, and the PI_{C} value according to the above Formula 2-3 were calculated.

The measured values and calculated values for each of the examples and comparative examples are described in Table 4 below.

### Evaluation Example: Roughness Measurement of Polished Surface

The polishing compositions of the respective examples and comparative examples were applied as slurry to measure the polishing rate of the copper film formed on a wafer having a diameter of 300 mm. For each thin film, the polishing rate was measured under the conditions of a polishing time of 60 seconds, a pressure of 2.2 psi, a carrier speed of 93 rpm, a platen speed of 87 rpm, and a slurry flow rate of 300 ml/min, and the polisher used was the AP-300 model manufactured by CTS.

Thereafter, the arithmetic mean roughness (Ra) according to ISO 4287 of the surface of the copper film polished by the polishing compositions of the respective examples and comparative examples was measured with an atomic force microscope (AFM), Park XE-100 model, manufactured by Park Systems.

The measured values for each example and comparative example are described in Table 5 below.

### Evaluation Example: Measurement of Defect Occurrence Frequency on Polished Surface

The polishing compositions of the respective examples and comparative examples were applied as slurry to polish the surface of a SiO₂ wafer. The polishing conditions were applied in the same manner as those used in the polishing rate measurement evaluation described above.

The number of defects formed on the surface of the polished SiO₂ wafer was measured using the wafer defect detector, model AIT-XP+, manufactured by KLA Tencor.

Subsequently, the polishing compositions of the respective examples and comparative examples were applied as slurry to polish the surface of a SiO₂ wafer, on which a copper pattern was formed. The measurement conditions were applied in the same manner as those used in the polishing rate measurement evaluation described above.

The number of defects formed on the surface of the polished patterned wafer was measured using the wafer defect detector, model AIT-XP+, manufactured by KLA Tencor.

The measurement results for each example and comparative example are described in Table 5 below.

### Evaluation Example: Evaluation of Dishing of Copper Wiring

The polishing compositions of the respective examples and comparative examples were applied as slurry to polish a first patterned wafer having a diameter of 300 mm. The first patterned wafer was formed such that, on an SiO₂ film in which a copper pattern with a line width of 1 μm was formed, a barrier film having a thickness of 160 nm including tantalum and tantalum nitride was formed. The polishing conditions were applied in the same manner as those used in the polishing rate measurement evaluation described above. After polishing, the dishing values of the copper wiring were measured by AFM at a center portion located at the center of the substrate surface, an edge portion located at the edge of the substrate surface, and a middle portion located at the midpoint of a line connecting the centers of the center portion and the edge portion.

Subsequently, the polishing compositions of the respective examples and comparative examples were applied as slurry to polish a second patterned wafer. The second patterned wafer was formed such that, on an SiO₂ film in which a copper pattern with a line width of 10 μm was formed, a barrier film having a thickness of 400 nm including tantalum and tantalum nitride was formed. The polishing conditions were applied in the same manner as those used in the polishing rate measurement evaluation described above. After polishing, the dishing values of the copper wiring were measured by AFM from the polished substrate surface.

The measurement results for each example and comparative example are described in Table 6 below.

TABLE 1

| | First Polishing | | Second Polishing Particle | | | | |
|---|---|---|---|---|---|---|---|
| | Particle Preparation | | Preparation Composition | | | | |
| | Composition | | | | Isopropyl | | |
| | TEOS | Ethanol | Water | Ammonia | alcohol | Reaction | Reaction |
| | (parts by | (parts by | (parts by | (parts by | (parts by | Temperature | time |
| Classification | weight) | weight) | weight) | weight) | weight) | (° C.) | (hour) |
| Preparation | 15 | 41 | 2 | 1 | 41 | 45 | 5 |
| Example 1 | | | | | | | |
| Preparation | 4.5 | 45.75 | 3 | 1 | 45.75 | 45 | 5 |
| Example 2 | | | | | | | |
| Preparation | 4.5 | 43.25 | 8 | 1 | 43.25 | 45 | 5 |
| Example 3 | | | | | | | |

TABLE 2

| | Polishing | | | |
|---|---|---|---|---|
| | Particle | | Zeta | |
| | Content | | Potential | |
| | (wt %) | D₅₀(nm) | (mV) | pH |
| Example 1 | 8 | 76 | −48 | 10.4 |
| Comparative | 16 | 80 | −55 | 10.4 |
| Example 1 | | | | |
| Comparative | 8 | 80 | −55 | 10.5 |
| Example 2 | | | | |
| Comparative | 8 | 85 | −54 | 10.4 |
| Example 3 | | | | |

TABLE 3

| | | | | BET | | |
|---|---|---|---|---|---|---|
| | | | | Specific | Micropore | Average |
| | | | | Surface | Specific | Diameter of |
| | | | | Area | Volume | Micropores |
| | Rps | Ap(m²/g) | As(m²/g) | (m²/g) | (cm³/g) | (nm) |
| Preparation | 1.1566 | 28.2603 | 24.4349 | 52.6952 | 0.0136 | 24.8160 |
| Example 1 | | | | | | |
| Preparation | 0.2561 | 9.3459 | 36.4962 | 45.8421 | 0.0044 | 13.7418 |
| Example 2 | | | | | | |
| Preparation | 0.2997 | 24.2554 | 80.9398 | 105.1952 | 0.0103 | 10.2189 |
| Example 3 | | | | | | |

TABLE 4

| | |
|---|---|
| Diameter of | Intensity |

| Secondary | Preparation | Preparation | Preparation |
|---|---|---|---|
| Particles (nm) | Example 1 | Example 2 | Example 3 |
| 0.4 | 0 | 0 | 0 |
| 0.463 | 0 | 0 | 0 |
| 0.536 | 0 | 0 | 0 |
| 0.621 | 0 | 0 | 0 |
| 0.719 | 0 | 0 | 0 |
| 0.833 | 0 | 0 | 0 |
| 0.965 | 0 | 0 | 0 |
| 1.12 | 0 | 0 | 0 |
| 1.29 | 0 | 0 | 0 |
| 1.5 | 0 | 0 | 0 |
| 1.74 | 0 | 0 | 0 |
| 2.01 | 0 | 0 | 0 |
| 2.33 | 0 | 0 | 0 |
| 2.7 | 0 | 0 | 0 |
| 3.12 | 0 | 0 | 0 |
| 3.62 | 0 | 0 | 0 |
| 4.19 | 0 | 0 | 0 |
| 4.85 | 0 | 0 | 0 |
| 5.61 | 0 | 0 | 0 |
| 6.5 | 0 | 0 | 0 |
| 7.53 | 0 | 0 | 0 |
| 8.72 | 0 | 0 | 0 |
| 10.1 | 0 | 0 | 0 |
| 11.7 | 0 | 0 | 0 |
| 13.5 | 0 | 0 | 0 |
| 15.7 | 0 | 0 | 0 |
| 18.2 | 0 | 0 | 0 |
| 21 | 0 | 0 | 0 |
| 24.4 | 0 | 0 | 0 |
| 28.2 | 0 | 0 | 0 |
| 32.7 | 0 | 0 | 0 |
| 37.8 | 1.63 | 0 | 0 |
| 43.8 | 5.74 | 0 | 0 |
| 50.7 | 11.1 | 1.92 | 1.89 |
| 58.8 | 15.8 | 9.23 | 7.93 |
| 68.1 | 18.3 | 18.1 | 15.4 |
| 78.8 | 17.7 | 23.4 | 20.7 |
| 91.3 | 14.4 | 22.5 | 21.4 |
| 106 | 9.5 | 16 | 17.5 |
| 122 | 4.6 | 7.5 | 10.7 |
| 142 | 1.21 | 1.38 | 4.13 |
| 164 | 0 | 0 | 0.324 |
| 190 | 0 | 0 | 0 |
| 220 | 0 | 0 | 0 |
| 255 | 0 | 0 | 0 |
| 295 | 0 | 0 | 0 |
| 342 | 0 | 0 | 0 |
| 396 | 0 | 0 | 0 |
| 459 | 0 | 0 | 0 |
| 531 | 0 | 0 | 0 |
| 615 | 0 | 0 | 0 |
| 712 | 0 | 0 | 0 |
| 825 | 0 | 0 | 0 |
| 955 | 0 | 0 | 0 |
| 1110 | 0 | 0 | 0 |
| 1280 | 0 | 0 | 0 |
| 1480 | 0 | 0 | 0 |
| 1720 | 0 | 0 | 0 |
| 1990 | 0 | 0 | 0 |
| 2300 | 0 | 0 | 0 |
| 2670 | 0 | 0 | 0 |
| 3090 | 0 | 0 | 0 |
| 3580 | 0 | 0 | 0 |
| 4150 | 0 | 0 | 0 |
| 4800 | 0 | 0 | 0 |
| 5560 | 0 | 0 | 0 |
| 6440 | 0 | 0 | 0 |
| 7460 | 0 | 0 | 0 |
| 8630 | 0 | 0 | 0 |

TABLE 5

| | Polishing | | | | | |
|---|---|---|---|---|---|---|
| | rate for | | Polishing | | Polishing | |
| | silicon | PI_{S} | rate for | PI_{T} | rate for | PI_{C} |
| | oxide film | (Å/(min · | barrier film | (Å/(min · | copper film | (Å/(min · |
| | (Å/min) | wt %)) | (Å/min) | wt %)) | (Å/min) | wt %)) |
| Example 1 | 1899 | 237.38 | 858 | 107.25 | 1178 | 147.25 |
| Comparative | 1834 | 114.625 | 758 | 47.375 | 1364 | 85.25 |
| Example 1 | | | | | | |
| Comparative | 1321 | 165.125 | 552 | 69 | 831 | 103.875 |
| Example 2 | | | | | | |
| Comparative | 1602 | 200.25 | 851 | 106.375 | 1624 | 203 |
| Example 3 | | | | | | |

TABLE 6

| | | Number of | Number of |
|---|---|---|---|
| | Ra value (Å) | defects (pcs) on | defects (pcs) on |
| | of copper | SiO₂ wafer | patterned wafer |
| | film after | surface after | surface after |
| | polishing | polishing | polishing |
| Example 1 | 3.73 | 611 | 473 |
| Comparative | 5.99 | 1343 | 1581 |
| Example 1 | | | |
| Comparative | 6.39 | 877 | 598 |
| Example 2 | | | |
| Comparative | 4.82 | 1246 | 1105 |
| Example 3 | | | |

TABLE 7

| | Center part | | Middle part | | Edge part | |
|---|---|---|---|---|---|---|
| | Dishing | Dishing | Dishing | Dishing | Dishing | Dishing |
| | value of | value of | value of | value of | value of | value of |
| | copper | copper | copper | copper | copper | copper |
| | wiring with | wiring with | wiring with | wiring with | wiring with | wiring with |
| | width 1 μm | width 10 μm | width 1 μm | width 10 μm | width 1 μm | width 10 μm |
| | (Å) | (Å) | (Å) | (Å) | (Å) | (Å) |
| Example 1 | 3 | 32 | 6 | 37 | 14 | 68 |
| Comparative | 7 | 37 | 9 | 44 | 16 | 73 |
| Example 1 | | | | | | |
| Comparative | 5 | 29 | 8 | 32 | 13 | 56 |
| Example 2 | | | | | | |
| Comparative | 9 | 39 | 10 | 51 | 24 | 91 |
| Example 3 | | | | | | |

In Table 5, Example 1 exhibited higher PI_{S} and PI_{T} values compared to the Comparative Examples. It is considered that this is because the irregular shape of the polishing particles of Example 1 contributes to an improvement in the polishing rate of the polishing composition.

In Table 6, Example 1 exhibited a lower Ra value compared to the Comparative Examples. This means that Example 1 may form a smoother polished surface compared to the Comparative Examples when polishing a copper film.

In the number of defects on the surface of a SiO₂ wafer after polishing and the number of defects on the surface of a patterned wafer, Example 1 exhibited a lower number of defects compared to the Comparative Examples. It is considered that this is because Example 1 includes a smaller amount of polishing particles having a large diameter compared to the other Comparative Examples, resulting in a lower frequency of scratches generated on the polished surface by the polishing particles.

In particular, the fact that Example 1 exhibited a significantly lower number of defects compared to Comparative Example 1 is considered to be because the polishing composition of Example 1 includes a lower content of polishing particles compared to Comparative Example 1.

In the copper wiring dishing evaluation of Table 7, Example 1 exhibited similar or lower dishing values compared to the Comparative Examples.

Although preferred embodiments have been described in detail above, the scope of the present invention is not limited thereto, and various modifications and improved forms using the basic concept of the embodiments defined in the following claims by those skilled in the art also fall within the scope of the present invention.

What is claimed is:

1. A polishing composition for semiconductor process comprising polishing particles,
wherein an Rps value calculated by the following Formula 1 is 0.5 to 2:
$$Rps = \frac{Ap}{As} \qquad [ Formula 1 ]$$
in [Formula 1],
Ap is a specific surface area of a micropore of the polishing particles, and
As is a specific surface area of an external surface of the polishing particles.

2. The polishing composition for semiconductor process of claim 1,
wherein the Ap is 25 m²/g to 50 m²/g.

3. The polishing composition for semiconductor process of claim 1,
wherein the As is 10 m²/g to 30 m²/g.

4. The polishing composition for semiconductor process of claim 1,
wherein a BET specific surface area of the polishing particles is 30 m²/g to 80 m²/g.

5. The polishing composition for semiconductor process of claim 1,
wherein a specific pore volume of the micropore of the polishing particles is 0.011 cm³/g to 0.2 cm³/g.

6. The polishing composition for semiconductor process of claim 1,
wherein the polishing particles comprise primary particles having an average diameter of 15 nm to 40 nm.

7. The polishing composition for semiconductor process of claim 6,
wherein the polishing particles further comprise secondary particles having an average diameter of 120 nm or more in an amount of 10 wt % or less.

8. The polishing composition for semiconductor process of claim 6,
wherein the polishing particles further comprise secondary particles having an average diameter of less than 50 nm in an amount of 10 wt % or less.

9. The polishing composition for semiconductor process of claim 1,
wherein the polishing composition comprises the polishing particles in an amount of 4 wt % to 12 wt %.

10. The polishing composition for semiconductor process of claim 1,
wherein a pH of the polishing composition is 8 to 12.

11. A method for manufacturing a substrate, comprising:
a process of polishing the substrate using the polishing composition for semiconductor process of claim 1 as a slurry.

12. Polishing particles,
wherein an Rps value calculated by the following Formula 1 is 0.5 to 2:
$$Rps = \frac{Ap}{As} \qquad [ Formula 1 ]$$
in [Formula 1],
Ap is a specific surface area of a micropore of the polishing particles, and
As is a specific surface area of an external surface of the polishing particles.

13. The polishing particles of claim 12,
wherein the Ap is 25 m²/g to 50 m²/g.

14. The polishing particles of claim 12,
wherein the As is 10 m²/g to 30 m²/g.

15. The polishing particles of claim 12,
wherein a BET specific surface area of the polishing particles is 30 m²/g to 80 m²/g.

16. The polishing particles of claim 12,
wherein a specific pore volume of micropore of the polishing particles is 0.011 cm³/g to 0.2 cm³/g.

17. The polishing particles of claim 12,
wherein the polishing particles comprise primary particles having an average diameter of 15 nm to 40 nm.

18. The polishing particles of claim 17,
wherein the polishing particles further comprise secondary particles having an average diameter of 120 nm or more.

19. The polishing particles of claim 17,
wherein the polishing particles further comprise secondary particles having an average diameter of less than 50 nm.
